(19) United States
(12) Patent Application Publication
(10) Pub. No.: US 2008/0237845 A1
(43) Pub. Date: Oct. 2, 2008

(54) SYSTEMS AND METHODS FOR REMOVING HEAT FROM FLIP-CHIP DIE

(76) Inventors: Jesse Jaejin Kim, Sunnyvale, CA (US); Bao Tran, San Jose, CA (US)

Correspondence Address: TRAN & ASSOCIATES, 6768 MEADOW VISTA CT., SAN JOSE, CA, 95135, US

(21) Appl. No.: 11/692,348

(22) Filed: Mar. 28, 2007

(51) Int. Cl. H01L 23/34

(52) U.S. Cl. 257/715; 257/E23.08

(57) ABSTRACT

A cooling apparatus includes a substrate; an integrated circuit (IC) die flip-bonded to the substrate; a thermally-conductive layer on one surface of the IC die; and a heat removal chamber having thermally-conductive microporous coat thermally coupled to the conductive layer.

### BACKGROUND

Flip-chips have been developed to satisfy the electronic industry's continual drive to lower cost, to increase the packaging density and to improve the performance while still maintaining or even improving the reliability of the circuits. In the flip-chip manufacturing process, a semiconductor chip is assembled face down onto circuit board. This is ideal for size considerations, because there is no extra area needed for contacting on the sides of the component (true also with TAB). The performance in high frequency applications is superior to other interconnection methods, because the length of the connection path is minimized. Flip chip technology is cheaper than wire bonding (true also with TAB) because bonding of all connections takes place simultaneously whereas with wire bonding one bond is made at a time. There are many different alternative processes used for flip-chip joining. A common feature of the joined structures is that the chip is lying face down to the substrate and the connections between the chip and the substrate are made using bumps of electrically conducting material.

While flip-chips have certain size and cost advantages, due to their compact size, they have limited heat dissipation capability. Integrated circuits such as microprocessors (CPUs) and graphics processing units (GPUs) generate heat when they operate and frequently this heat must be dissipated or removed from the integrated circuit die to prevent overheating. One technique for cooling an integrated circuit die is to attach a fluid-filled microchannel heat exchanger to the die. A typical microchannel heat exchanger consists of a silicon substrate in which microchannels have been formed using a subtractive microfabrication process such as deep reactive ion etching or electro-discharge machining. Typical microchannels are rectangular in cross-section. The microchannels improve a heat exchanger's coefficient of heat transfer by increasing the conductive surface area in the heat exchanger. Heat conducted into the fluid filling the channels can be removed simply by withdrawing the heated fluid.

Typically, the microchannel heat exchanger is part of a closed loop cooling system that uses a pump to cycle a fluid such as water between the microchannel heat exchanger where the fluid absorbs heat from a microprocessor or other integrated circuit die and a remote heat sink where the fluid is cooled. Heat transfer between the microchannel walls and the fluid is greatly improved if sufficient heat is conducted into the fluid to cause it to vaporize. Such two-phase cooling enhances the efficiency of the microchannel heat exchanger because significant thermal energy above and beyond that which can be simply conducted into the fluid is consumed in overcoming the fluid s latent heat of vaporization. This latent heat is then expelled from the system when the fluid vapor condenses back to liquid form in the remote heat sink. Water is a particularly useful fluid to use in two-phase systems because it is cheap, has a high heat (or enthalpy) of vaporization and boils at a temperature that is well suited to cooling integrated circuits.

The heat removal capacity of microchannel heat exchangers can be enhanced by vertically stacking multiple layers of microchannel structures to form a stacked microchannel heat exchanger. Stacked microchannel heat exchangers are more efficient at removing heat from ICs because each additional layer of microchannels doubles the surface area for heat exchange per unit area of the heat exchanger.

Conventionally, heat exchangers are not physically coupled directly to an IC die or package but, rather, are coupled to a metallic heat spreader that is itself coupled to the IC die or package. In the context of mobile computing systems the size of a typical heat exchanger often precludes coupling the heat exchanger directly to the heat spreader thus requiring the addition of a heat pipe or other thermally conductive structure to provide the physical and thermal coupling between the heat exchanger and the heat spreader. Heat pipes or similar devices are bulky and occupy valuable space within a mobile computing system.

U.S. Pat. No. 7,115,987 discloses an integrated stacked microchannel heat exchanger and heat spreaders for cooling integrated circuit (IC) dies and packages and cooling systems. A stacked microchannel heat exchanger is operatively and thermally coupled to an IC die or package using an interstitial solder or a solderable material in combination with solder. The integrated stacked microchannel heat exchanger and heat spreaders may be employed in a closed loop cooling system including a pump and a heat rejecter. The integrated stacked microchannel heat exchanger and heat spreaders are configured to support either a two-phase or a single-phase heat transfer process using a working fluid such as water.

### SUMMARY

In one aspect, an apparatus includes a substrate; an integrated circuit (IC) die flip-bonded to the substrate; a thermally-conductive layer on one surface of the IC die; and a heat removal chamber having thermally-conductive microporous coat thermally coupled to the conductive layer.

Implementations of the above aspect may include one or more of the following. The thermally conductive layer can be a layer of solder such as interstitial solder. The layer of solder can be formed from at least one of the following metals: copper (Cu), gold (Au), nickel (Ni), aluminum (Al), titanium (Ti), tantalum (Ta), silver (Ag) and Platinum (Pt). The thermally conductive layer can be an adhesive disposed between the heat removal chamber and the surface of the IC die. The adhesive can be a thermal adhesive. The adhesive can be a silicon to silicon bonding adhesive. The adhesive can be a polymer compound. For example, the adhesive can be bisbenzocyclobutene. A substrate can be positioned to which the IC die is flip-bonded.

In another aspect, a computer system includes a motherboard; an integrated circuit (IC) die flip-bonded to the motherboard; a thermally-conductive layer on one surface of the IC die; and a heat removal chamber having thermally-conductive microporous coat thermally coupled to the conductive layer.

Advantages of the system may include one or more of the following. The system is thin and can be used to cool flip-chip dies. The system ensures that the heat absorbing surface or coating contacts the coolant liquid to ensure an efficient transfer of heat from the heat source to the liquid and to the rest of the module. The system allows the system to run at top performance while minimizing the risk of failure due to overheating. The system provides a boiling cooler with a vessel in a simplified design using inexpensive non-metal material or low cost liquid coolant in combination with a boiling enhancement surface or coating.

Other advantages of the invention may include one or more of the following. The cooler described in this invention overcomes many drawbacks of those conventional electronic cooling apparatus in terms of low-power consumption, high heat-transfer efficiency, low cost, flexibility in physical shapes and ability to miniaturize, making it very suitable for a plurality of cooling applications including electronic component or system cooling.

### BRIEF DESCRIPTION OF THE DRAWINGS

FIG. 1 shows an embodiment of a flip-chip heat removal apparatus.

FIG. 2 is a diagrammatic fragmentary perspective view of an apparatus which is a portable computer.

### DESCRIPTION

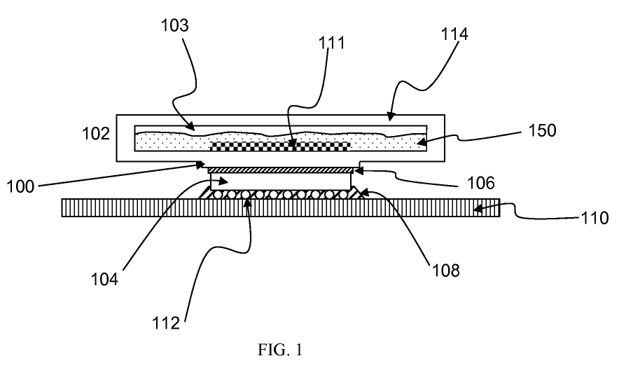

FIG. 1 illustrates in cross-sectional view one embodiment of an integrated heat exchanger and heat spreader 100 for flip-chip bonded systems. The heat exchanger 102 includes a chamber 114 and heat spreader 100 physically and thermally coupled to an IC die 104 by a layer of thermally conductive material 106 such as solder or epoxy. An epoxy underfill 108 is typically employed to strengthen the interface between the die 104 and the substrate 110 that the die 104 is flip-bonded to by a plurality of solder bumps 112. While the embodiment of FIG. 1 illustrates die 104 flip-bonded by a plurality of solder bumps 112, other methods of bonding die 104 to substrate 110 may be used in combination with the heat exchanger without departing from the scope or spirit of the invention.

A heat spreader can be used to provide additional heat dissipation. In one embodiment, the cavity between a spreader and the chip itself becomes the chamber, with the coat applied on top of the die—and/or—on the bottom side of the spreader.

The heat exchanger 102 includes a liquid container, housing or chamber 114 that contains a liquid coolant. Ionic liquids (room temperature liquid salts) can be used as coolants based on their thermal stability, extremely low vapor pressure and other properties. Non-dielectric liquid coolant such as water is preferred due to low cost and low environmental issues. Dielectric liquid coolants can also be used. Aromatics coolant such as synthetic hydrocarbons of aromatic chemistry (i.e., diethyl benzene [DEB], dibenzyl toluene, diaryl alkyl, partially hydrogenated terphenyl) can be used. Silicate-ester such as Coolanol 25R can be used. Aliphatic hydrocarbons of paraffinic and iso-paraffinic type (including mineral oils) can be used as well. Another class of coolant chemistry is dimethyl- and methyl phenyl-poly (siloxane) or commonly known as silicone oil—since this is a synthetic polymeric compound, the molecular weight as well as the thermo-physical properties (freezing point and viscosity) can be adjusted by varying the chain length. Silicone fluids are used at temperatures as low as −100° C. and as high as 400° C. These fluids have excellent service life in closed systems in the absence of oxygen. Also, with essentially no odor, the non-toxic silicone fluids are known to be workplace friendly. However, low surface tension gives these fluids the tendency to leak around pipe-fittings, although the low surface tension improves the wetting property. Fluorinated compounds such as perfluorocarbons (i.e., FC-72, FC-77) hydrofluoroethers (HFE) and perfluorocarbon ethers (PFE) have certain unique properties and can be used in contact with the electronics.

Non-dielectric liquid coolants offer attractive thermal properties, as compared with the dielectric coolants. Non-dielectric coolants are normally water-based solutions. Therefore, they possess a very high specific heat and thermal conductivity. De-ionized water is a good example of a widely used electronics coolant. Other popular non-dielectric coolant chemistries include Ethylene Glycol (EG), Propylene Glycol (PG), Methanol/Water, Ethanol/Water, Calcium Chloride Solution, and Potassium Formate/Acetate Solution, among others.

The housing or chamber 114 has a Thermally-Conductive Microporous Coating (TCMC) 111 that is in thermal communication with the thermally conductive material 106. The liquid coolant 150 partially fills the chamber 114, at least partially covering the TCMC 111 surface area so that the heat flux conducted from the heating die 104 can induce the nucleate boiling of the liquid at the microporous surface of TCMC 111. In this boiling cooler, the nucleate boiling heat transfer is significantly augmented by the TCMC 111 and becomes a dominant way to spread heat throughout the chamber. Vapor coming out of the liquid boiling is held within the open space of chamber 103. Conduction in this case becomes less important so that the whole body-shell of the chamber 114, excepting the thermal conductive surface between the conductive material 106 and the TCMC 111, can be made of non-metal such as plastic material. As a trade-off for fully using plastic material, one may still use typical metal such as aluminum or copper for the major portion of the vessel including the side to contact the heat-generating device and all extruded fin structure for convection heat exchange to take advantage of its high thermal conductivity, but the end-caps can be made of plastic to reduce manufacture cost. In one embodiment, the major portion of body-shells of the vessel chambers including extruded fins and extended plate can be made of non-metal material comprising plastic, vinyl, or paper, which is much less expensive than any metal. Not only the material cost is lower, capability of plastic molding for those extruded fin structure also reduces the manufacturing cost comparing to processing metal. In addition, the non-metal body-shells can also be electrically insulating which provides an important advantage over the conventional cooler with electrically conducting metal shells for certain electronics cooling applications.

In yet another embodiment of this cooler in combination with nucleate boiling, the chamber shells including fins can be constructed by utilizing molded and baked copper powder, which provides better thermal conductivity than those modules using all-plastic materials but still costs less than those using all-machined metals. Similarly, thermally conductive plastic composite material can be used for constructing the boiling cooler according to current invention. For cooling some devices/systems with relatively large thermal load, in addition to the nucleate boiling heat transfer within the cooling vessel, conductive body-shell is necessary for more efficient heat exchange with cooler's environment.

In one embodiment, the TCMC can be a microporous coat or a boiling surface enhancement. In one implementation, a coating technique combines the advantages of a mixture batch type and thermally-conductive microporous structures. The microporous surface is created using particles of various sizes comprising any metal which can be bonded by the soldering process including nickel, copper, aluminum, silver, iron, brass, and various alloys in conjunction with a thermally conductive binder. The coating is applied on the surface of a substrate while mixed with a solvent. The solvent is vaporized after the application prior to heating the surface sufficiently to melt the binder to bind the particles. The mixture batch type application is an inexpensive and easy process, not requiring extremely high operating temperatures. The coating surface created by this process is insensitive to its thickness due to high thermal conductivity of the binder. Therefore, large size cavities can be constructed in the microporous structures for some poorly wetting but potentially low cost fluids, such as water, without causing serious degradation of boiling enhancement. This makes the boiling cooler keep its high cooling efficiency for various types of liquid coolants simply by adjusting the size of metal particles to allow the size range of porous cavities formed fit well with the surface tension of the selected liquid to optimize boiling heat transfer performance.

The first phase of the coolant can be a liquid phase and the second phase can be a vapor phase. The coolant can be water or any suitable coolant. Additionally, boiling heat transfer can be done with direct component immersion in a dielectric liquid as a means of providing heat transfer coefficients large enough to meet forecasted dissipation levels, while maintaining reduced component temperatures. Dielectric liquids (3M Fluorinert family) can be used because they are chemically inert and electrically non-conducting. Their use with boiling heat transfer introduces significant design challenges which include reducing the wall superheat at boiling incipience, enhancing nucleate boiling heat transfer rates, and increasing the maximum nucleate boiling heat flux (CHF). Water can also be used for low cost.

The boiling enhancement coating provides a surface enhancement which creates increased boiling nucleation sites, decreases the incipient superheats, increases the nucleate boiling heat transfer coefficient and increases the critical heat flux. This surface enhancement is particularly advantageous when applied to microelectronic components such as silicon chips that cannot tolerate the high temperature environment required to bond existing heat sinks onto the chip, or mechanical treatments such as sandblasting, and is also particularly advantageous when applied to phase change heat exchanger systems that require chemically stable, strongly bonded surface microstructures. The boiling enhancement coating can be a composition of matter such as a glue, a solvent and cavity-generating particles. This composition is applied to a surface and then cured by low heat or other means, including but not limited to air drying for example, which evaporates the solvent and causes the glue with embedded particles to be bonded to the surface. The embedded particles provide an increased number of boiling nucleation sites. As used herein, “paint” means a solution or suspension which is in liquid or semiliquid form and which may be applied to a surface and when applied, can be cured to adhere to the surface and to form a thin layer or coat on that surface. The paint may be applied by any means such as spread with a brush, dripped from a brush or any other instrument or sprayed, for example. Alternatively, the surface may be dipped into the paint. By curing, is meant that the solvent will be evaporated, by exposure to the rays of a lamp, for example and the remaining composition which includes the suspended particles will adhere to the surface. As used herein, “glue” means any compound which will dissolve in an easily evaporated solvent and will bond to the particles and to the target surface. Some types of glue will be more compatible with certain applications and all such types of such glue will fall within the scope of the present claimed invention. The glue to be used in the practice of the claimed invention would be any glue which exhibits the above mentioned characteristics and which is preferably a synthetic or naturally occurring polymer. Examples of types of glue that could be used in the present invention include ultraviolet activated glue or an epoxy glue, for example. Epoxy glues are well known glues which comprise reactive epoxide compounds which polymerize upon activation. Ultraviolet glues are substances which polymerize upon exposure to ultraviolet rays. Preferably such glues would include 3M 1838-L A/13 and most preferably the thermally conductive epoxies Omegabond 101 or Omegatherm 201 (Omega Engineering, Stamford, Conn.) and the like or any glue which would adhere to the surface and to the particles. Another preferred glue is a brushable ceramic glue. Brushable ceramic glue is a low viscosity, brushable epoxy compound. Preferred brushable ceramic glues have a viscosity of about 28,000 cps and a maximum operating temperature of about 350.degree.F., and most preferred is Devcon Brushable Ceramic Glue. Thermally conductive epoxies are those with thermal conductivities in the range of about 7 to about 15 BTU/(ft.sup.2) (sec) (.degreeF./in). The particles of the present invention may be any particles which would generate cavities on the surface in the manner disclosed herein. As used herein, “cavity-generating particles” means particles which when applied to a surface, or when fixed in a thin film on a surface, form depressions in the surface of from about 0.5 .um to about 10 um in width, which depressions are suitable for promoting boiling nucleation. Preferred particles disclosed herein include crystals, flakes and randomly shaped particles, but could also include spheres or any other shaped particle which would provide the equivalent cavities. The particles are also not limited by composition. Such particles could comprise a compound such as an organic or inorganic compound, a metal, an alloy, a ceramic or combinations of any of these. One consideration is that for certain applications, the particles should be electrically non-conducting. Some preferred particles might comprise silver, iron, copper, diamond, aluminum, ceramic, or an alloy such as brass and particularly preferred particles are silver flakes or, for microelectronic applications, diamond particles, copper particles or aluminum.

In one embodiment, a boiling enhancement composition can include solvent, glue and cavity-generating particles in a ratio of about 10 ml solvent to about 0.1 ml of glue to from about 0.2 grams to about 1.5 grams of cavity-generating particles. Alternatively, the preferred composition is in a ratio of about 10 ml solvent to 0.1 ml of glue to about 1.5 grams of cavity-generating particles. It is understood that compositions of different ratios will be applicable to different utilities and that the ratios disclosed herein are not limiting in any way to the scope of the claimed invention. For example, an embodiment of the present invention is a composition of matter comprising solvent, glue and cavity-generating particles wherein the composition is 85-98% (v/v) solvent, 0.5-2% (v/v) glue and 1.5-15% (w/v) cavity-generating particles. By % (v/v) is meant liquid volume of component divided by total volume of suspension. By % (w/v) is meant grams of component divided by 100 ml of suspension.

The boiling enhancement composition may be added to the surface in any manner appropriate to the particular application. For example, the composition may be painted or dripped onto the surface, or even sprayed onto the surface. Alternatively, the surface or object may be dipped into the composition of the present invention. Following any of these applications, the enhancing composition would then be cured. It is contemplated that the composition of the present invention may also be incorporated into the surface as it is being manufactured and the boiling heat transfer enhancement would be an integral part of the surface. More details on the boiling enhancement coating is described in U.S. Pat. No. 5,814,392, the content of which is incorporated by reference.

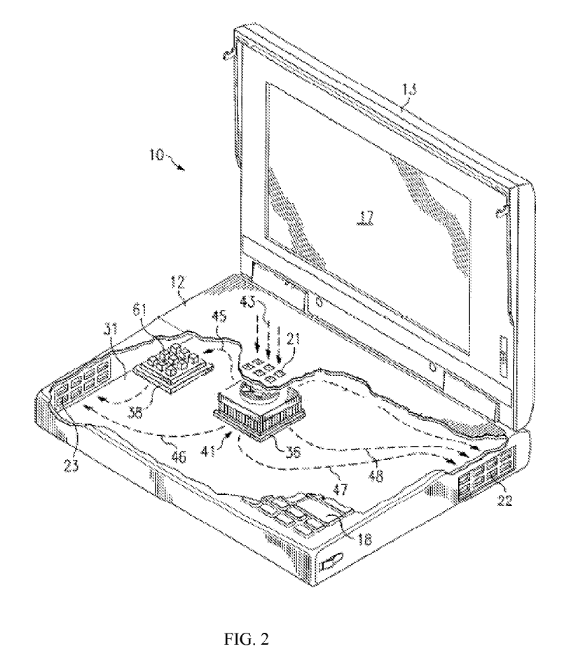

The cooler can operate fanless or with a fan to provide extra heat removing capability, as illustrated in more details next. FIG. 2 is a diagrammatic fragmentary perspective view of an apparatus which is a portable computer 10, and which embodies aspects of the present invention. The computer 10 includes a housing 12 and a lid 13. The lid 13 is pivotally supported on the housing 12 for movement between an open position which is shown in FIG. 1, and a closed position in which the lid is adjacent the top surface of the housing 12. The lid 13 contains a liquid crystal display (LCD) panel 17 of a type commonly used in portable computers.

A plurality of manually operable keys 18 are provided on top of the housing 12, and collectively define a computer keyboard. In the disclosed embodiment, the keyboard conforms to an industry-standard configuration, but it could alternatively have some other configuration. The top wall of the housing 12 has, in a central portion thereof, a cluster of openings 21 which each extend through the top wall. The openings 21 collectively serve as an intake port. The housing 12 also has, at an end of the right sidewall which is nearest the lid 13, a cluster of openings 22 that collectively serve as a discharge port. Further, the left sidewall of the housing 12 has, near the end remote from the lid 13, a cluster of openings 23 that collectively serve as a further discharge port.

A circuit board 31 is provided within the housing 12. The circuit board 31 has a large number of components thereon, but for clarity these components are not all depicted in FIG. 1. In particular, FIG. 2 shows only three components 36, 37 and 38, each of which produces heat that must be dissipated. The integrated circuit 36 contains a high-performance processor, which in the disclosed embodiment is a known device that can be commercially obtained under the trademark PENTIUM from Intel Corporation or ATHLON from AMD Corporation, both of Santa Clara, Calif. However, the present invention is compatible with a wide variety of integrated circuits, including those containing other types of processors.

A cooling assembly 41 is mounted on top of the integrated circuit 36, in thermal communication therewith. The cooling assembly 41 may be mounted on the integrated circuit 36 using a thermally conductive epoxy, or in any other suitable manner that facilitates a flow of heat between the integrated circuit 36 and the cooling assembly 41.

The cooling assembly 41 draws air into the housing 12 through the intake port defined by the openings 21, as indicated diagrammatically at 43. This air flow passes through the cooling assembly 41, and heat from the cooling assembly 41 is transferred to this air flow. Respective portions of this air flow exit from the cooling assembly 41 in a variety of different horizontal directions, and then travel to and through the discharge port defined by the openings 22 or the discharge port defined by the openings 23. The air flow travels from the cooling assembly 41 to the discharge ports along a number of different flow paths. Some examples of these various flow paths are indicated diagrammatically in FIG. 2 by broken lines 45-49. As air flows from the cooling assembly 41 to the openings 22 and 23 that define the two discharge ports, the air travels over and picks up heat from components other than the processor, including the components 37 and 38, as well as other components that are not specifically shown in FIG. 2.

The pattern of air flow from the cooling assembly 41 to the discharge ports depends on the number of discharge ports, and on where the discharge ports are located. Further, when there are two or more discharge ports, the relative sizes of the discharge ports will affect the pattern of air flow, where the size of each port is the collective size of all of the openings defining that port. For example, if the collective size of the openings in one of the discharge ports exceeds the collective size of the openings in the other discharge port, more air will flow to and through the former than the latter. With this in mind, hot spots can be identified in the circuitry provided on the circuit board 31, and then the location and effective size of each discharge port can be selected so as to obtain an air flow pattern in which the amount of air flowing past each identified hot spot is more than would otherwise be the case.

The integrated circuit 38 has a heat sink 61 mounted on the top surface thereof, in a manner so that the heat sink 61 and the integrated circuit 38 are in thermal communication. In the embodiment of FIG. 2, the heat sink 61 is secured to the integrated circuit 38 using a thermally conductive epoxy, but it could alternatively be secured in place in any other suitable manner. The heat sink 61 is made of a metal such as aluminum, or a metal alloy that is primarily aluminum, and has a base with an array of vertically upwardly extending projections. As air travels from the cooling assembly 41 along the path 45 to the discharge port defined by the openings 23, it flows over the heat sink 61 and through the projections thereof. Heat generated by the integrated circuit 38 passes to the heat sink 61, and then from the heat sink 61 to the air flowing along path 45. The heat sink 61 transfers heat from the integrated circuit 38 to the air flow 45 at a lower temperature than would be the case if the heat sink 61 was omitted and heat had to be transferred directly from the integrated circuit 38 to the air flow.

The above arrangement is used for laptop cooling. A similar arrangement can be used for cooling graphics cards that mount active ICs up-side down and such application is contemplated by the inventor as well.

While the present invention has been described with reference to particular figures and embodiments, it should be understood that the description is for illustration only and should not be taken as limiting the scope of the invention. Many changes and modifications may be made to the invention, by one having ordinary skill in the art, without departing from the spirit and scope of the invention. For example, additional heat dissipation layers may be added to enhance heat dissipation of the integrated circuit device. Additionally, various packaging types and IC mounting configurations may be used, for example, ball grid array, pin grid array, etc. Furthermore, although the invention has been described in a particular orientations, words like “above,” “below,” “overlying,” “beneath,” “up,” “down,” “height,” etc. should not be construed to require any absolute orientation.

The foregoing described embodiments are provided as illustrations and descriptions. They are not intended to limit the invention to the precise form described. In particular, it is contemplated that functional implementation of invention described herein may be implemented equivalently in hardware, software, firmware, and/or other available functional components or building blocks. Other variations and embodiments are possible in light of above teachings, and it is thus intended that the scope of invention not be limited by the description, but rather by the following claims

1. An apparatus comprising:
a substrate;
an integrated circuit (IC) die flip-bonded to the substrate;
a thermally-conductive layer on one surface of the IC die; and
a heat removal chamber having thermally-conductive microporous coat thermally coupled to the conductive layer.

2. The apparatus of claim 1, wherein the thermally conductive layer comprises a layer of solder.

3. The apparatus of claim 2, wherein the layer of solder comprises interstitial solder.

4. The apparatus of claim 2, wherein the layer of solder is formed from at least one of the following metals: copper (Cu), gold (Au), nickel (Ni), aluminum (Al), titanium (Ti), tantalum (Ta), silver (Ag) and Platinum (Pt).

5. The apparatus of claim 1, wherein the thermally conductive layer comprises an adhesive disposed between the heat removal chamber and the surface of the IC die.

6. The apparatus of claim 5, wherein the adhesive comprises a thermal adhesive.

7. The apparatus of claim 5, wherein the adhesive comprises a silicon to silicon bonding adhesive.

8. The apparatus of claim 7, wherein the adhesive comprises a polymer compound.

9. The apparatus of claim 8, wherein the adhesive comprises bisbenzocyclobutene.

10. The apparatus of claim 1, wherein the die forms a part of one side of the heat removal chamber, and the thermally-conductive layer is a boiling enhancement surface.

11. The apparatus of claim 1, further comprising a substrate to which the IC die is flip-bonded.

12. A computer system, comprising:
a motherboard;
an integrated circuit (IC) die flip-bonded to the motherboard;
a thermally-conductive layer on one surface of the IC die; and
a heat removal chamber having thermally-conductive microporous coat thermally coupled to the conductive layer.

13. The system of claim 11, wherein the thermally conductive layer comprises a layer of solder.

14. The system of claim 13, wherein the layer of solder comprises interstitial solder.

15. The system of claim 13, wherein the layer of solder is formed from at least one of the following metals: copper (Cu), gold (Au), nickel (Ni), aluminum (Al), titanium (Ti), tantalum (Ta), silver (Ag) and Platinum (Pt).

16. The system of claim 12, wherein the thermally conductive layer comprises an adhesive disposed between the heat removal chamber and the surface of the IC die.

17. The system of claim 16, wherein the adhesive comprises a thermal adhesive.

18. The system of claim 16, wherein the adhesive comprises a silicon to silicon bonding adhesive.

19. The system of claim 18, wherein the adhesive comprises one of: a polymer compound, a bisbenzocyclobutene compound.

20. The system of claim 12, wherein the chamber comprises a cavity between a heat spreader and the IC die.

21. The system of claim 20, comprising a coat applied on a top of the die or on a bottom of the spreader.
